(19) United States
(12) Patent Application Publication
(10) Pub. No.: US 2015/0188039 A1
(43) Pub. Date: Jul. 2, 2015

(54) Embedded Resistors with Oxygen Gettering Layers

(71) Applicant: Intermolecular Inc., San Jose, CA (US)

(72) Inventors: Yun Wang, San Jose, CA (US); Vidyut Gopal, Sunnyvale, CA (US); Mihir Tendulkar, Mountain View, CA (US)

(73) Assignee: Intermolecular Inc., San Jose, CA (US)

(21) Appl. No.: 14/140,755

(22) Filed: Dec. 26, 2013

(51) Int. Cl. H01L 45/00; H01L 27/24

(52) U.S. Cl. CPC H01L 45/12; H01L 45/1253; H01L 45/146; H01L 45/147; H01L 45/1608; H01L 27/2463

(57) ABSTRACT

Provided are resistive random access memory (ReRAM) cells and methods of fabricating thereof. The ReRAM cells may include a first layer operable as a bottom electrode and a second layer operable to switch between at least a first resistive state and a second resistive state. The ReRAM cells may include a third layer including a first oxygen getter material and a fourth layer including a metal silicon nitride. The ReRAM cells may further include a fifth layer including a second oxygen getter material. The first oxygen getter material and the second oxygen getter material may be more reactive with oxygen than the metal silicon nitride. A work function of the first oxygen getter material and a work function of the second oxygen getter material may be substantially lower than a work function of the metal silicon nitride. The ReRAM cells may include a sixth layer operable as a top electrode.

### BACKGROUND

Nonvolatile memory is computer memory capable of retaining stored information even when unpowered. Non-volatile memory is typically used for secondary storage or long-term persistent storage and may be used in addition to volatile memory, which loses the stored information when unpowered. Nonvolatile memory can be permanently integrated into computer systems (e.g., solid state hard drives) or can take the form of removable and easily transportable memory cards (e.g., USB flash drives). Nonvolatile memory is becoming more popular because of its small size/high density, low power consumption, fast read and write rates, retention, and other characteristics.

Flash memory is a common type of nonvolatile memory because of its high density and low fabrication costs. Flash memory is a transistor-based memory device that uses multiple gates per transistor and quantum tunneling for storing the information on its memory device. Flash memory uses a block-access architecture that can result in long access, erase, and write times. Flash memory also suffers from low endurance, high power consumption, and scaling limitations.

The constantly increasing speed of electronic devices and storage demand drive new requirements for nonvolatile memory. For example, nonvolatile memory is expected to replace hard drives in many new computer systems. However, transistor-based flash memory is often inadequate to meet the requirements for nonvolatile memory. New types of memory, such as resistive random access memory, are being developed to meet these demands and requirements.

### SUMMARY

Provided are resistive random access memory (ReRAM) cells and methods of fabricating thereof. The ReRAM cells may include resistive switching nonvolatile memory elements that may include a first layer operable as a bottom electrode and a second layer (“variable resistance layer”) operable to switch between at least a first resistive state and a second resistive state in response to an applied voltage. The resistive switching nonvolatile memory elements may also include a third layer that includes a first oxygen getter material and a fourth layer that includes a metal silicon nitride. The fourth layer may have a substantially constant resistance at voltages less than or equal to the applied voltage. The resistive switching nonvolatile memory elements may further include a fifth layer that includes a second oxygen getter material. The first oxygen getter material and the second oxygen getter material may each be more reactive with oxygen than the metal silicon nitride. Moreover, a first work function of the first oxygen getter material and a second work function of the second oxygen getter material may each be substantially lower than a third work function of the metal silicon nitride. The resistive switching nonvolatile memory elements may also include a sixth layer operable as a top electrode.

In some embodiments, the third layer and the fifth layer each may include one of hafnium, zirconium, and yttrium. Moreover, the third layer and the fifth layer may each have a thickness of between about 10 nm and 30 nm. In some embodiments, the fourth layer includes tantalum silicon nitride. Moreover, the fourth layer may have a thickness of between about 5 nm and 10 nm. The fifth layer may directly interface the fourth layer. The resistive switching nonvolatile memory elements may also include a seventh layer that has a substantially constant resistance at voltages less than or equal to the applied voltage. The seventh layer may directly interface the fifth layer. The resistive switching nonvolatile memory elements may further include an eighth layer formed between the seventh layer and the sixth layer. The eighth layer may include a third oxygen getter material having a fourth work function that is substantially lower than a fifth work function of a material in the seventh layer. In some embodiments, the seventh layer includes a metal silicon nitride, and the eighth layer includes one of zirconium, yttrium and hafnium.

According to some embodiments, the fourth layer includes a dopant. The dopant may be one of hafnium, zirconium, or yttrium. In some embodiments, the second layer includes one of hafnium oxide, titanium oxide, strontium titanium oxide, and hafnium silicon oxide. Moreover, the second layer may include, at least in part, amorphous silicon oxide. In some embodiments, the first layer and the sixth layer may include titanium nitride.

Also disclosed herein are methods for forming resistive switching nonvolatile memory elements. The methods may include forming a first layer operable as a bottom electrode and forming a second layer operable to switch between at least a first resistive state and a second resistive state in response to an applied voltage. The methods may also include forming a third layer that includes a first oxygen getter material and forming a fourth layer that includes a metal silicon nitride. The fourth layer may have a substantially constant resistance. The methods may further include forming a fifth layer that includes a second oxygen getter material. The first oxygen getter material and the second oxygen getter material may each be more reactive with oxygen than the metal silicon nitride. Moreover, a first work function of the first oxygen getter material and a second work function of the second oxygen getter material may each be substantially lower than a third work function of the metal silicon nitride. The methods may also include forming a sixth layer operable as a top electrode.

In some embodiments, the methods may also include forming a seventh layer having a substantially constant resistance at voltages less than or equal to the applied voltage. The seventh layer may directly interface the fifth layer. The methods may also include forming an eighth layer between the seventh layer and the sixth layer. The eighth layer may include a third oxygen getter material having a fourth work function that is substantially lower than a fifth work function of a material in the seventh layer. According to some embodiments, the forming of the first layer, the second layer, the third layer, the fourth layer, the fifth layer, and the sixth layer include using an atomic layer deposition process. Moreover, in some embodiments, the forming of the fourth layer includes forming a film of a metal silicon nitride and pulsing any of hafnium, zirconium, or yttrium during the forming of the film. According to some embodiments, the forming of the fourth layer includes forming a laminate of a metal silicon nitride and any of hafnium, zirconium, or yttrium. In some embodiments, the forming of the first layer, the second layer, the third layer, the fourth layer, the fifth layer, and the sixth layer include using a physical vapor deposition process.

These and other embodiments are described further below with reference to the figures.

### BRIEF DESCRIPTION OF THE DRAWINGS

To facilitate understanding, the same reference numerals have been used, where possible, to designate common components presented in the figures. The drawings are not to scale and the relative dimensions of various elements in the drawings are depicted schematically and not necessarily to scale. Various embodiments can readily be understood by considering the following detailed description in conjunction with the accompanying drawings.

FIG. 1A illustrates a schematic representation of a ReRAM cell prior to initial forming operation, in accordance with some embodiments.

FIGS. 1B and 1C illustrate schematic representations of the ReRAM cell in its high resistive state (HRS) and low resistive state (LRS), in accordance with some embodiments.

FIG. 2A illustrates a plot of a current passing through a unipolar ReRAM cell as a function of a voltage applied to the ReRAM cell, in accordance with some embodiments.

FIG. 2B illustrates a plot of a current passing through a bipolar ReRAM cell as a function of a voltage applied to the ReRAM cell, in accordance with some embodiments.

FIG. 3 illustrates a schematic representation of a ReRAM cell including an embedded resistor, a variable resistance layer, one or more oxygen getter layers, and other components, in accordance with some embodiments.

FIG. 4 illustrates a schematic representation of another ReRAM cell including an embedded resistor, a variable resistance layer, one or more oxygen getter layers, and other components, in accordance with some embodiments.

FIG. 5 illustrates a process flowchart corresponding to a method of fabricating a ReRAM cell, in accordance with some embodiments.

FIGS. 6A and 6B illustrate schematic views of memory arrays including multiple ReRAM cells, in accordance with some embodiments.

### DETAILED DESCRIPTION

A detailed description of various embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

### Introduction

A ReRAM cell exhibiting resistive switching characteristics generally includes multiple layers formed into a stack, such as a “metal-insulator-metal” (MIM) stack. The stack includes two conductive layers operating as electrodes, which are identified as “M” and may include a metal, but may also include other types of conductive materials, such as doped silicon. The stack also includes an insulator layer provided in between the two electrodes and identified as “I”. The insulator layer changes its resistive properties when certain switching voltages are applied to the layer or, more generally, to the ReRAM cell including this layer. Due to its variable resistance characteristics, the insulator layer may be also referred to as a variable resistance layer. These changes in resistive properties are used to store data. For example, when two different resistive states are identified (e.g., a high resistive state and a low resistive state) for a ReRAM cell, one state may be associated with a logic “zero”, while the other state may be associated with a logic “one” value. Similar approaches may be used when three or more resistive states may be identified for the same ReRAM cell leading to various multibit architectures.

The switching voltages may be applied as series of pulses and may be generally referred to as switching voltage profiles or, more specifically, set voltage profiles and reset voltage profiles. For example, a switching voltage pulse may be used to change (“set” or “reset”) the resistive state followed by a smaller reading voltage pulse to determine the current state of the ReRAM cell at that time. Unlike the switching voltage pulse, the reading pulse is specifically configured to avoid changing the resistive state of the ReRAM cell and is configured only to determine the current state. The switching pulse may be repeated if the desired resistive state is not reached. The switching pulses may alternate with the reading pulses for feedback control. The switching pulses may vary from one to another based on their potential (e.g., a gradual increase in the potential), duration, and other characteristics. The reading pulses may be the same. The process of applying the switching pulses and reading pulses may continue until the desired resistive state is reached.

The change in resistance of the resistive switching layer is a dynamic process that needs to be well controlled to prevent over-programming. For example, when the resistive switching layer is switched from its high resistive state (HRS) to its low resistive state (LRS), a rapid drop in resistance associated with this switch may cause an excessive current through the resistive switching layer and an over-programming. The over-programming occurs when change in the resistance continues even after the resistive switching layer reaches its desirable resistance. One approach to prevent over-programming is by using very short pulses, e.g., about 50 nanoseconds, followed by a reading pulse. If the desired resistive state is not reached, another pulse is applied. The process of applying switching and reading pulses may be repeated until the desired resistance is not reached. However, shorter pulses have their own inherent limitations, such as requiring more pulses or higher voltages to achieve the same switching result, which may consume more power than fewer, longer, lower-voltage pulses. Furthermore, even during a relatively short switching pulse, the change in resistance may be sufficiently large to result in current spiking and over-programming. In some embodiments, the difference in resistances between the LRS and the HRS may be more than an order of magnitude to allow the read pulses to easily differentiate between the two states.

To prevent current spiking and over-programming, an embedded resistor is connected in series with the resistive switching layer and is used to limit the current through the resistive switching layer. The embedded resistor effectively functions as a voltage divider within the ReRAM cell. Unlike the resistive switching layer, the embedded resistor maintains a constant resistance throughout the entire operation of the cell. As a relative change of the overall ReRAM cell resistance (expressed as a ratio of the change in the resistance of the ReRAM cell to the overall initial resistance) when the resistive switching layer goes between the LRS and the HRS is less for ReRAM cells with embedded resistors than for similar cells without embedded resistor. This voltage divider/constant resistance characteristic of the embedded resistor helps to prevent the current spiking and over-programming.

In some embodiments, the ReRAM cells may include embedded resistors which may be made of metal silicon nitride (e.g., TaSiN) cermets that may suppress or prevent over-programming of variable resistance layers within the ReRAM cells. However, conventional methods of forming the metal silicon nitrides inadvertently include an undesirable amount of oxygen within the embedded resistors, which may, for example, produce TaSiON. The oxygen content may further increase when the ReRAM cell is subjected to a 750 C forming gas anneal if there is a small oxygen leak. For example, an embedded resistor that includes a metal silicon nitride may include about 40% oxygen in either the surface or the bulk of the layer. The undesired oxygen content creates non-linearity in the resistance characteristics of the embedded resistor. For example, the resistance may be much higher at low voltage/current operation, and may increase the forming voltage when implemented with a variable resistance layer.

As disclosed herein, embedded resistors may include an “oxygen getter” which may be a reactive material that reacts with oxygen and has a lower work function than the metal silicon nitride of the embedded resistor. Accordingly, the oxygen getter material may form an oxide more easily and readily than the material of the embedded resistor. The oxygen getter may be included in or stacked with the embedded resistor to ensure that the oxygen getter has sufficient oxygen exchange with the entire volume of the embedded resistor to reduce and prevent the oxidation of the embedded resistor. The oxygen getter may be hafnium, zirconium, or yttrium. The low work function of the oxygen getter may cause the oxygen getter to react with the oxygen, thus increasing the potential barrier of the embedded resistor and maintaining substantially linear resistance characteristics despite the application of a heat treatment, such as an anneal. In some embodiments, the embedded resistor has a thickness of less than about 10 nm to ensure oxygen transfer from the entire volume of the embedded resistor to the oxygen getter. The thickness of the oxygen getter layer may be greater than 5 nm to ensure that the volume of this layer is sufficient to oxidize and trap oxygen. More specifically, the embedded resistor may have a thickness of between about 2 nm and 10 nm, and the oxygen getter layer may have a thickness of between about 10 nm and 30 nm. The oxygen getter layer and the embedded resistor may be formed by a physical vapor deposition process or an atomic layer deposition (ALD) process. In some embodiments, the oxygen getter layer and the embedded resistor may be integrated into the same components, e.g., a nanolaminate stack formed by ALD in which portions of the oxygen getter alternate with portions of the embedded resistor. Moreover, according to some embodiments, the embedded resistor may be doped with zirconium, hafnium, or yttrium. These and other features will be discussed in greater detail below.

### Examples of Nonvolatile ReRAM Cells and their Switching Mechanisms

A brief description of ReRAM cells is provided for context and better understanding of various features associated with embedded resistors in the ReRAM cells. As stated above, a ReRAM cell includes a dielectric material formed into a layer exhibiting resistive switching characteristics. A dielectric, which is normally insulating, can be made to conduct through one or more conductive paths formed after application of a voltage. The conductive path formation can arise from different mechanisms, including defects, metal migration, and other mechanisms further described below. Once one or more conductive paths (e.g., filaments) are formed in the dielectric component of a memory device, these conductive paths may be reset (or broken resulting in a high resistance) or set (or re-formed resulting in a lower resistance) by applying certain voltages. Without being restricted to any particular theory, it is believed that resistive switching corresponds to migration of defects within the variable resistance layer and, in some embodiments, across one interface formed by the resistive switching voltage, when a switching voltage is applied to the layer.

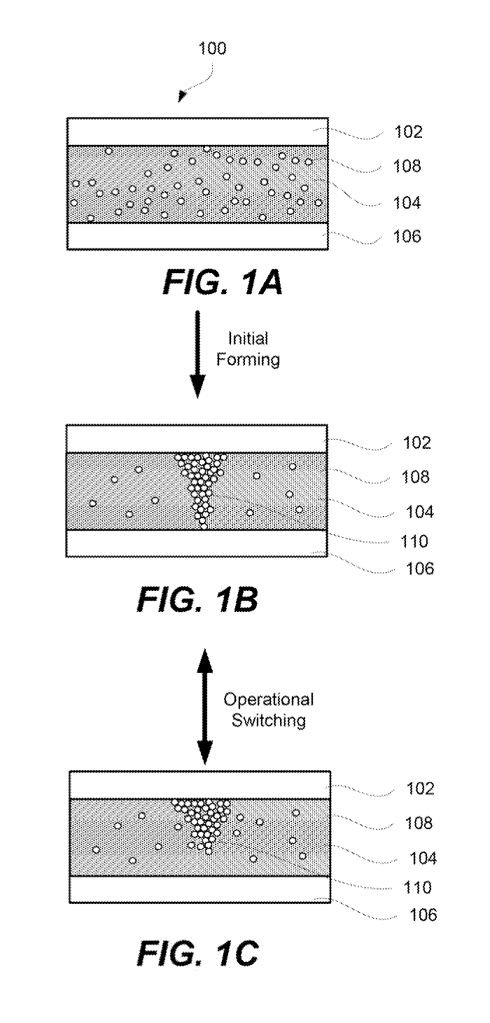

FIG. 1A illustrates a schematic representation of ReRAM cell 100 including first electrode 102, second electrode 106, and variable resistance layer 104 disposed in between first electrode 102 and second electrode 106. It should be noted that the “first” and “second” references for electrodes 102 and 106 are used solely for differentiation and not to imply any processing order or particular spatial orientation of these electrodes. ReRAM cell 100 may also include other components, such as an embedded resistor, diode, diffusion barrier layer, and other components. ReRAM cell 100 is sometimes referred to as a memory element or a memory unit.

First electrode 102 and second electrode 106 may be used as conductive lines within a memory array or other types of devices that ReRAM cell is integrated into. As such, electrode 102 and 106 are generally formed from conductive materials. As stated above, one of the electrodes may be reactive electrode and act as a source and as a reservoir of defects for the variable resistance layer. That is, defects may travel through an interface formed by this electrode with the variable resistance layer (i.e., the reactive interface).

Variable resistance layer 104 which may be initially formed from a dielectric material and later can be made to conduct through one or more conductive paths formed within the layer by applying first a forming voltage and then a switching voltage. To provide this resistive switching functionality, variable resistance layer 104 includes a concentration of electrically active defects 108, which may be at least partially provided into the layer during its fabrication. For example, some atoms may be absent from their native structures (i.e., creating vacancies) and/or additional atoms may be inserted into the native structures (i.e., creating interstitial defects). Charge carriers may be also introduced as dopants, stressing lattices, and other techniques. Regardless of the types all charge carriers are referred to as defects 108.

FIG. 1A is a schematic representation of ReRAM cell 100 prior to initial formation of conductive paths, in accordance with some embodiments. Variable resistance layer 104 may include some defects 108. Additional defects 108 may be provided within first electrode 102 and may be later transferred to variable resistance layer 104 during the formation operation. In some embodiments, the variable resistance layer 104 has substantially no defects prior to forming operation and all defects are provided from first electrode 102 during forming. Second electrode 106 may or may not have any defects. It should be noted that regardless of presence or absence of defects in second electrode 106, substantially no defects are exchanged between second electrode 106 and variable resistance layer 104 during forming and/or switching operations.

During the forming operation, ReRAM cell 100 changes its structure from the one shown in FIG. 1A to the one shown in FIG. 1B. This change corresponds to defects 108 being arranged into one or more continuous paths within variable resistance layer 104 as, for example, schematically illustrated in FIG. 1B. Without being restricted to any particular theory, it is believed that defects 108 can be reoriented within variable resistance layer 104 to form these conductive paths as, for example, schematically shown in FIG. 1B. Furthermore, some or all defects 108 forming the conductive paths may enter variable resistance layer 104 from first electrode 102. For simplicity, all these phenomena are collectively referred to as reorientation of defects within ReRAM cell 100. This reorientation of defects 108 occurs when a certain forming voltage is applied to electrodes 102 and 106. In some embodiments, the forming operation also conducted at elevated temperatures to enhanced mobility of the defects within ReRAM cell 100. In general, the forming operation is considered to be a part of the fabrication of ReRAM cell 100, while subsequent resistive switching is considered to be a part of operation of ReRAM cell.

Resistive switching involves breaking and reforming conductive paths through variable resistance layer 104, i.e., switching between the state schematically illustrated in FIG. 1B and the state schematically illustrated in FIG. 1C. The resistive switching is performed by applying switching voltages to electrodes 102 and 106. Depending on magnitude and polarity of these voltages, conductive path 110 may be broken or formed back again. These voltages may be substantially lower than forming voltages (i.e., voltages used in the forming operation) since much less mobility of defects is needed during switching operations. For example, hafnium oxide based resistive layers may need about 7 Volts during their forming but can be switched using voltages less than 4 Volts.

The state of variable resistance layer 104 illustrated in FIG. 1B is referred to as a low resistive state (LRS), while the state illustrated in FIG. 1C is referred to as a high resistive state (HRS). The resistance difference between the LRS and HRS is due to different number and/or conductivity of conductive paths that exists in these states, i.e., variable resistance layer 104 has more conductive paths and/or less resistive conductive paths when it is in the LRS than when it is in the HRS. It should be noted that variable resistance layer 104 may still have some conductive paths while it is in the HRS, but these conductive paths are fewer and/or more resistive than the ones corresponding to the LRS.

When switching from its LRS to HRS, which is often referred to as a reset operation, variable resistance layer 104 may release some defects into first electrode 102. Furthermore, there may be some mobility of defects within variable resistance layer 104. This may lead to thinning and, in some embodiments, breakages of conductive paths as shown in FIG. 1C. Depending on mobility within variable resistance layer 104 and diffusion through the interface formed by variable resistance layer 104 and first electrode 102, the conductive paths may break closer to the interface with second electrode 106, somewhere within variable resistance layer 104, or at the interface with first electrode 102. This breakage generally does not correspond to complete dispersion of defects forming these conductive paths and may be a self-limiting process, i.e., the process may stop after some initial breakage occurs.

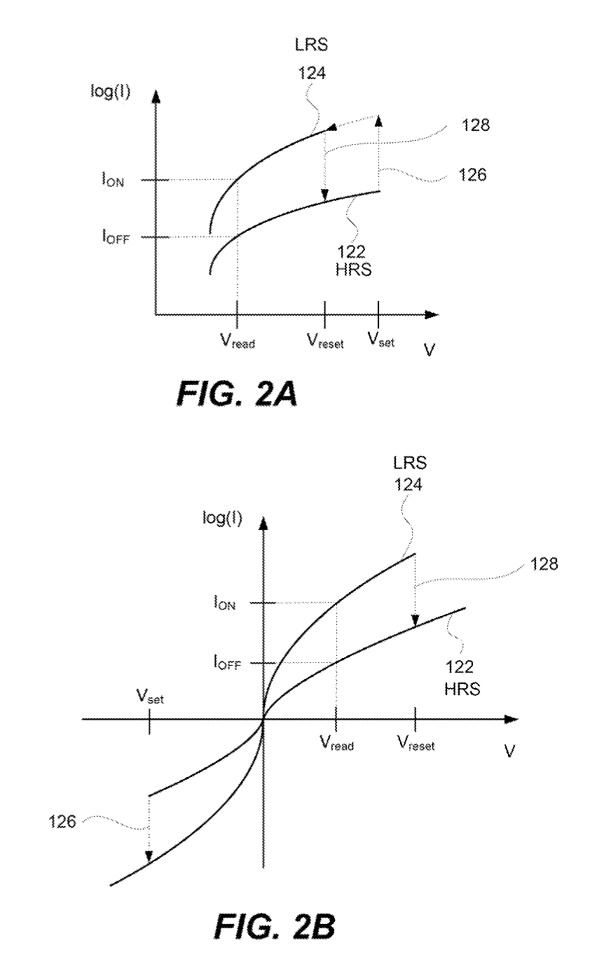

When switching from its HRS to LRS, which is often referred to as a set operation, variable resistance layer 104 may receive some defects from first electrode 102. Similar to the reset operation described above, there may be some mobility of defects within variable resistance layer 104. This may lead to thickening and, in some embodiments, reforming of conductive paths as shown in FIG. 1B. In some embodiments, a voltage applied to electrodes 102 and 106 during the set operation has the same polarity as a voltage applied during the reset operation. This type of switching is referred to as unipolar switching. Alternatively, a voltage applied to electrodes 102 and 106 during the set operation may have different polarity as a voltage applied during the reset operation. This type of switching is referred to as bipolar switching. Setting and resetting operations may be repeated multiple times as will now be described with reference to FIGS. 2A and 2B.

Specifically, FIG. 2A illustrates a plot of a current passing through a unipolar ReRAM cell as a function of a voltage applied to the ReRAM cell, in accordance with some embodiments. FIG. 2B illustrates the same type of a plot for a bipolar ReRAM cell, in accordance with some embodiments. The HRS is defined by line 122, while the LRS is defined by 124 in both plots. Each of these states is used to represent a different logic state, e.g., the HRS may represent logic one (“1”) and LRS representing logic zero (“0”) or vice versa. Therefore, each ReRAM cell that has two resistive states may be used to store one bit of data. It should be noted that some ReRAM cells may have three and even more resistive states allowing multi-bit storage in the same cell.

The overall operation of the ReRAM cell may be divided into a read operation, set operation (i.e., turning the cell “ON” by changing from its HRS to LRS), and reset operation (i.e., turning the cell “OFF” by changing from its LRS to HRS). During the read operation, the state of the ReRAM cell or, more specifically, the resistive state of its resistance of variable resistance layer can be sensed by applying a sensing voltage to its electrodes. The sensing voltage is sometimes referred to as a “READ” voltage or simply a reading voltage and indicated as V_{READ} in FIG. 2. If the ReRAM cell is in its HRS (represented by line 122 in FIGS. 2A and 2B), the external read and write circuitry connected to the electrodes will sense the resulting “OFF” current (I_{OFF}) that flows through the ReRAM cell. As stated above, this read operation may be performed multiple times without changing the resistive state (i.e., switching the cell between its HRS and LRS). In the above example, the ReRAM cell should continue to output the “OFF” current (I_{OFF}) when the read voltage (V_{READ}) is applied to the electrodes for the second time, third time, and so on.

Continuing with the above example, when it is desired to turn “ON” the cell that is currently in the HRS switch, a set operation is performed. This operation may use the same read and write circuitry to apply a set voltage (V_{SET}) to the electrodes. Applying the set voltage forms one or more conductive paths in the variable resistance layer as described above with reference to FIGS. 1B and 1C. The switching from the HRS to LRS is indicated by dashed line 126 in FIGS. 2A and 2B. The resistance characteristics of the ReRAM cell in its LRS are represented by line 124. When the read voltage (V_{READ}) is applied to the electrodes of the cell in this state, the external read and write circuitry will sense the resulting “ON” current (I_{ON}) that flows through the ReRAM cell. Again, this read operation may be performed multiple times without switching the state of the ReRAM cell.

At some point, it may be desirable to turn “OFF” the ReRAM cell by changing its state from the LRS to HRS. This operation is referred to as a reset operation and should be distinguished from set operation during which the ReRAM cell is switched from its HRS to LRS. During the reset operation, a reset voltage (V_{RESET}) is applied to the ReRAM cell to break the previously formed conductive paths in the variable resistance layer. Switching from a LRS to HRS is indicated by dashed line 128. Detecting the state of the ReRAM cell while it is in its HRS is described above.

Overall, the ReRAM cell may be switched back and forth between its LRS and HRS many times. Read operations may be performed in each of these states (between the switching operations) one or more times or not performed at all. It should be noted that application of set and reset voltages to change resistive states of the ReRAM cell involves complex mechanisms that are believed to involve localized resistive heating as well as mobility of defects impacted by both temperature and applied potential.

In some embodiments, the set voltage (V_{SET}) is between about 100 mV and 10V or, more specifically, between about 500 mV and 5V. The length of set voltage pulses (t_{SET}) may be less than about 100 milliseconds or, more specifically, less than about 5 milliseconds and even less than about 100 nanoseconds. The read voltage (V_{READ}) may be between about 0.1 and 0.5 of the write voltage (V_{SET}). In some embodiments, the read currents (I_{ON} and I_{OFF}) are greater than about 1 mA or, more specifically, is greater than about 5 mA to allow for a fast detection of the state by reasonably small sense amplifiers. The length of read voltage pulse (t_{READ}) may be comparable to the length of the corresponding set voltage pulse (t_{SET}) or may be shorter than the write voltage pulse (t_{RESET}). ReRAM cells should be able to cycle between LRS and HRS between at least about 10³ times or, more specifically, at least about 10⁷ times without failure. A data retention time (t_{RET}) should be at least about 5 years or, more specifically, at least about 10 years at a thermal stress up to 85° C. and small electrical stress, such as a constant application of the read voltage (V_{READ}). Other considerations may include low current leakage, such as less than about 40 A/cm² measured at 0.5 V per 20 Å of oxide thickness in HRS.

### Examples of ReRAM Cells

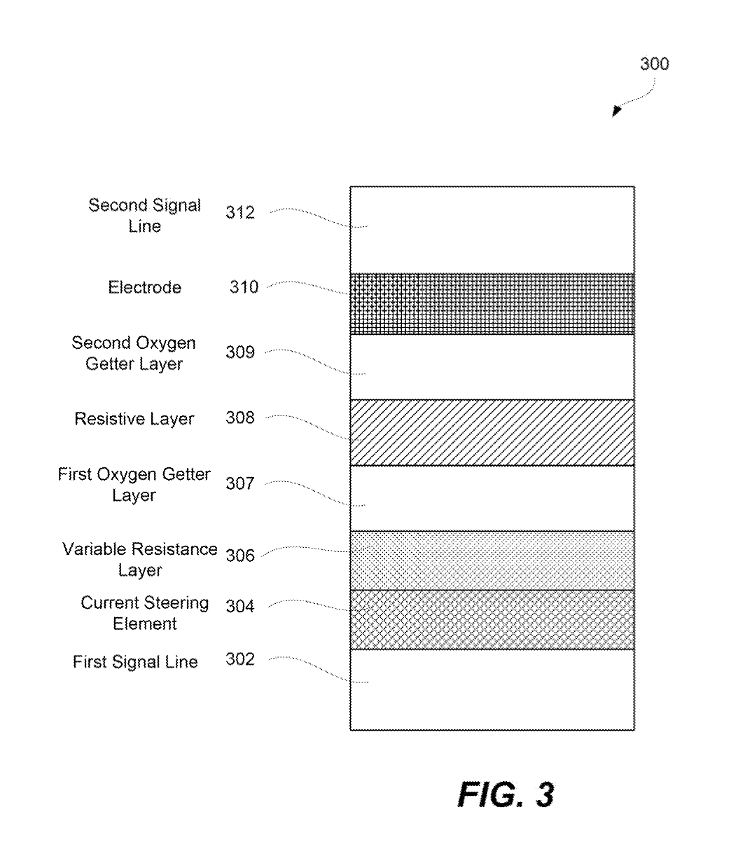

FIG. 3 illustrates a schematic representation of a ReRAM cell including a resistive layer, a variable resistance layer, one or more oxygen getter layers, and other components, in accordance with some embodiments. ReRAM cell 300 may include first signal line 302, current steering element 304, variable resistance layer 306, first oxygen getter layer 307, resistive layer 308, second oxygen getter layer 309, intermediate electrode 310, and a second signal line 312. The “first” and “second” terminology is used herein only for differentiating reasons and does not imply any deposition order or spatial orientation of the layers unless specifically noted. In some embodiments, ReRAM cell 300 has more or fewer layers. For example, an intermediate layer may be disposed between electrode 310 and second oxygen getter layer 309 in order to improve electrical connection between electrode 310 and second oxygen getter layer 309. Furthermore, current steering element 304 and/or intermediate electrode 310 may be omitted from ReRAM cell 300.

In the example illustrated in FIG. 3, a portion of current steering element 304 is also operable as another intermediate electrode interfacing variable resistance layer 306. Likewise, when intermediate electrode 310 is not present, a portion of resistive layer 308 may be operable as an intermediate electrode. Regardless of these configurations one electrode (standalone or a part of another component) interfacing variable resistance layer 306 may be an inert electrode and may not exchange defects with variable resistance layer 306. Another electrode (standalone or a part of another component) may be active and may exchange defects with variable resistance layer 306. For example, a titanium nitride electrode may accept and release oxygen vacancies into variable resistance layer 306, while a doped polysilicon electrode may form a passivation silicon oxide layer that blocks defects from going in and out of variable resistance layer 306. In the example illustrated in FIG. 3, current steering element 304 may include a bottom p-doped polysilicon portion, which interfaces first signal line 302, a top n-doped polysilicon portion, which interfaces variable resistance layer 306 and is operable as an electrode, more specifically, an inert electrode.

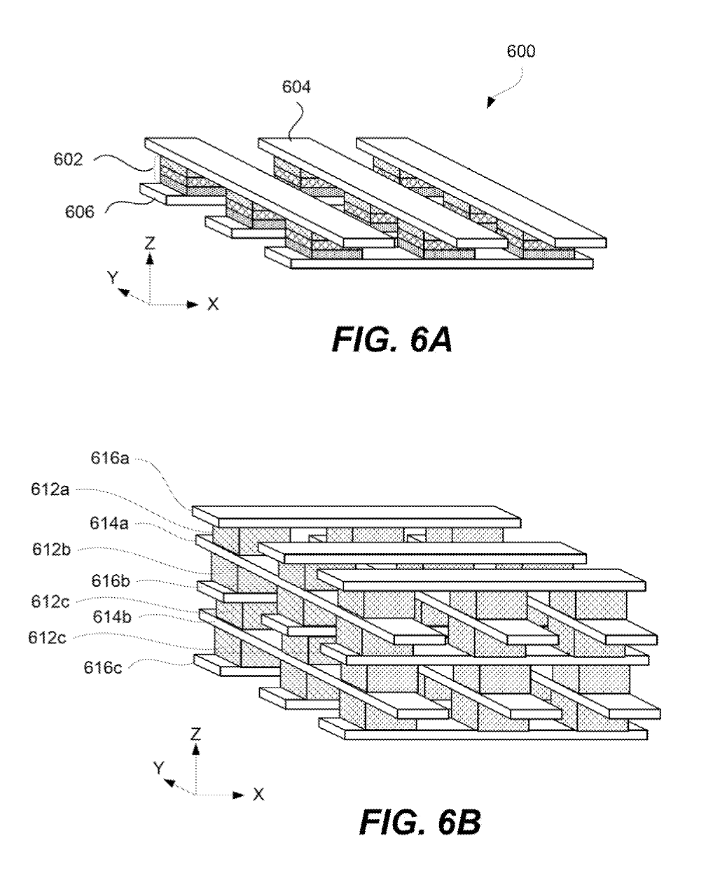

In some embodiments, the electrodes may be sufficiently conductive to be used as signal lines. Alternatively, signal lines and electrodes may be separate components as, for example, illustrated in FIG. 3. First signal line 302 and second signal line 312 provide electrical connections to ReRAM cell 300. For example, first signal line 302 and/or second signal line 312 extend between multiple ReRAM cells, which may be cells provided in the same row or the same column of a memory array as further described below with reference to FIGS. 6A and 6B. First signal line 302 and second signal line 312 may be made from conductive materials, such as n-doped polysilicon, p-doped polysilicon, titanium nitride, ruthenium, iridium, platinum, and tantalum nitride. The signal lines may have a thickness of less than about 100 nanometers (nm), such as less than about 50 nm and even less than about 10 nm. Thinner electrodes may be formed using atomic layer deposition (ALD) techniques.

Current steering element 304, if one is present, may be an intervening electrical component, such as a p-n junction diode, p-i-n diode, transistor, or other similar device disposed between first signal line 302 and second signal line 312. As such, current steering element 304 is connected in series with variable resistance layer 306. In some embodiments, current steering element 304 may include two or more layers of semiconductor materials, such as two or more doped silicon layers, that are configured to direct the flow of current through the device. Current steering element 304 may be a diode that includes a p-doped silicon layer, an un-doped intrinsic layer, and an n-doped silicon layer. These layers are not specifically identified in FIG. 3. The overall resistance of current steering element 304 may be between about 1 kilo-Ohm and about 100 Mega-Ohm. The overall resistance generally depends on the type of current steering element 304 and direction of the current flow through current steering element 304 (e.g., forward or reversed biased). In some embodiments, current steering element 304 may include one or more nitrides. For example, current steering element 304 may be a layer of titanium nitride.

Variable resistance layer 306 may be fabricated from a dielectric material, such as a metal oxide material or other similar material that can be switched between two or more stable resistive states. For example, variable resistance layer may include one of hafnium oxide, titanium oxide, strontium titanium oxide, and hafnium silicon oxide. In some embodiments, variable resistance layer 306 is fabricated from silicon oxide. The silicon oxide may be amorphous, which may be less than 5% crystalline as determined by X-ray diffraction. Accordingly, variable resistance layer 306 may be a layer of SiO₂ that is formed on and directly interfaces current steering element 304. Moreover, variable resistance layer 306 may have a thickness of between about 1 nm to about 100 nm, such as between about 2 nm and 20 nm or, more specifically, between about 5 nm and 10 nm. For example, variable resistance layer 306 may have a thickness of about 10 nm. Thinner variable resistance layers may be deposited using ALD, while thicker variable resistance layers may be deposited using may be deposited using ALD as well as physical vapor deposition (PVD) and, in some embodiments, chemical vapor deposition (CVD).

Resistive layer 308 may be a layer that is configured to have a substantially constant resistance at voltages less than or equal to one or more voltages which may be applied to ReRAM cell 300 during operational conditions. Resistive layer 308 may be fabricated from one of metal oxides, metal oxynitrides, metal silicon nitrides, metal silicon oxynitrides, metal aluminum nitrides, metal aluminum oxynitrides, metal boron nitrides, or metal boron oxynitrides. Specific examples of materials suitable for resistive layer 308 include metal silicon nitrides such as tantalum silicon nitride, hafnium silicon nitride, and molybdenum silicon nitride. In some embodiments, resistive layer 308 may have a thickness of between about 5 nm and 10 nm. Moreover, a footprint (i.e., cross-sectional area) of resistive layer 308 may be between about 20 nanometers-square and 100 nanometers-square or, more specifically, between about 30 nanometers-square and 60 nanometers-square, such as about 60 nanometers-square.

According to some embodiments, resistive layer 308 may be operable as an embedded resistor that limits a current that passes through ReRAM cell 300. In some embodiments, an oxygen content of resistive layer 308 may affect one or more electrical properties of resistive layer 308. For example, a relatively high oxygen content may result during a conventional deposition process, in which an oxygen content may be about 40 atomic % in a surface or bulk area of resistive layer 308. Such a high oxygen content may produce undesirable electrical characteristics, such as a non-linear electrical resistance in which resistive layer 308 has a high resistance during low voltage/current operation of ReRAM cell 300 thus making low voltage operation problematic. In conventional ReRAM cells, such high oxygen contents may result as part of a conventional deposition process in which a resistive layer may inadvertently be exposed to and react with oxygen. However, ReRAM cells as disclosed herein may include oxygen getter layers which may be formed adjacent to a resistive layer, such as resistive layer 308, and may control an oxygen content of resistive layer 308 to ensure that the oxygen content of resistive layer 308 remains relatively low. In this way, the oxygen getter layers may ensure that resistive layer 308 maintains a linear electrical resistance even during low voltage/current operation of ReRAM cell 300.

Accordingly, ReRAM cell may include one or more oxygen getter layers, such as first oxygen getter layer 307 and second oxygen getter layer 309. In some embodiments, an oxygen getter layer may include an oxygen getter material that is more reactive with oxygen than a material of resistive layer 308, which may be a metal silicon nitride. Moreover, the oxygen getter material included in the oxygen getter layers may include a material that has a work function that is substantially lower than the work function of the material included in resistive layer 308. Thus, materials included in the oxygen getter layers may react with oxygen instead of resistive layer 308 and effectively absorb oxygen which may otherwise react with and be included in resistive layer 308. In some embodiments, the oxygen getter layers may include a material such as zirconium, yttrium, or hafnium. In some embodiments, the oxygen getter layers may directly interface resistive layer 308 such that both a top surface and bottom surface of resistive layer 308 interface an oxygen getter layer. As shown in FIG. 3, first oxygen getter layer 307 may directly interface a bottom surface of resistive layer 308 and second oxygen getter layer 309 may directly interface a top surface of resistive layer 308. The close proximity of the oxygen getter layers to resistive layer 308 ensures that the oxygen getter layers will effectively remove oxygen from resistive layer 308.

In some embodiments, the oxygen getter layers may have a thickness or width configured or determined based on a thickness of resistive layer 308. For example, the oxygen getter layers may be configured to have a width that is sufficient to absorb substantially all oxygen from resistive layer 308. Similarly, resistive layer 308 may have a width or thickness that is configured or determined based on a thickness of one or more of the oxygen getter layers. In this way, the oxygen getter layers may be configured to have a capacity capable of absorbing substantially all oxygen from resistive layer 308 and may also be close enough to resistive layer 308 to effectively absorb oxygen from both the surface and bulk of resistive layer 308. For example, resistive layer 308 may be less than 10 nm thick. In this example, first oxygen getter layer 307 and second oxygen getter layer 309 may each be between about 5 nm and 10 nm thick. It will be appreciated that first oxygen getter layer 307 and second oxygen getter layer 309 may have the same or different thicknesses.

In some embodiments, a thickness of one or more oxygen getter layers may be determined based on a size of ReRAM cell 300. For example, larger ReRAM cells may be susceptible to a larger content of oxygen reacting with resistive layer 308. Accordingly, a greater thickness may be used for the oxygen getter layers to react with and absorb all of the oxygen. Smaller ReRAM cells may be susceptible to a smaller oxygen content and may include thinner oxygen getter layers. In this way, a thickness of first oxygen getter layer 307 and second oxygen getter layer 309 may be determined based on a critical dimension associated with ReRAM cell 300, such as a thickness or footprint of ReRAM cell 300.

Electrode 310 may be fabricated from a conductive material that has a desirable conductivity and work function, such as p-type polysilicon, n-type polysilicon, transition metals, transition metal alloys, transition metal nitrides, or transition metal carbides. For example, electrode 310 may include one or more of titanium (Ti), tungsten (W), tantalum (Ta), cobalt (Co), molybdenum (Mo), nickel (Ni), vanadium (V), hafnium (Hf) aluminum (Al), copper (Cu), platinum (Pt), palladium (Pd), iridium (Ir), or ruthenium (Ru). Electrode 310 may include titanium/aluminum alloy and/or a silicon-doped aluminum. In some embodiments, electrode 310 may be formed from titanium, tantalum, aluminum, or titanium nitride. Electrode 310 may be between about 5 nm and about 500 nm thick or, more specifically, between about 10 nm and about 100 nm thick.

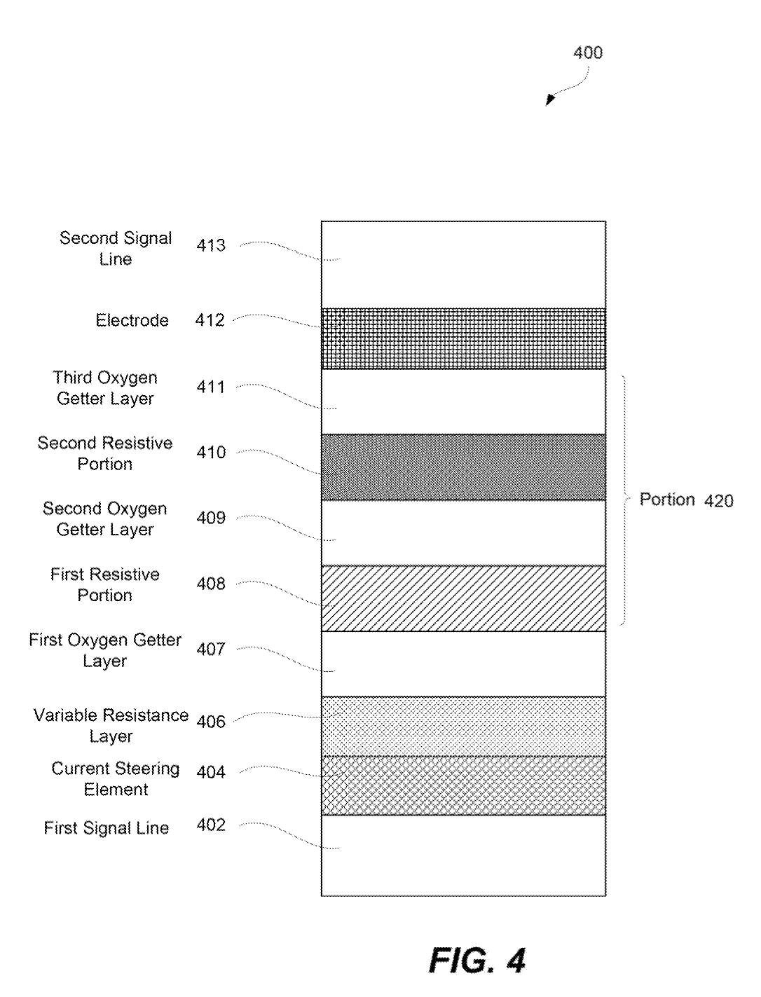

FIG. 4 illustrates a schematic representation of another ReRAM cell including an embedded resistor, a variable resistance layer, one or more oxygen getter layers, and other components, in accordance with some embodiments. As similarly discussed previously, a ReRAM cell, such as ReRAM cell 400, may include first signal line 402, current steering element 404, variable resistance layer 406, electrode 412, and second signal line 413. In some embodiments, the oxygen getter layer and the embedded resistor or resistive layer of ReRAM cell 400 may be integrated with each other as a nanolaminate stack formed by an atomic layer deposition (ALD) process in which portions of the oxygen getter layer alternate with portions of the resistive layer. For example, a resistive layer may include a material such as a metal silicon nitride. The oxygen getter layer may include an oxygen getter material, such as hafnium, zirconium, or yttrium. A laminate stack may be formed that includes alternating layers of the metal silicon nitride and the oxygen getter material, as will be discussed in greater detail below with reference to portion 420. Accordingly, multiple layers of oxygen getter material may be interleaved with various portions of a resistive layer. When interleaved in this way, a resistive layer which may be relatively thick, such as between about 20 nm to 50 nm, may be deposited as different resistive portions or layers within a laminate stack while ensuring that the oxygen getter material may effectively remove oxygen from the entire bulk of the resistive layer.

For example, ReRAM cell 400 may include first oxygen getter layer 407, first resistive portion 408, second oxygen getter layer 409, second resistive portion 410, and third oxygen getter layer 411. The oxygen getter layers may include a material that is more reactive with oxygen than a material of the resistive portions, which may be a metal silicon nitride. Moreover, the material included in the oxygen getter layers may include a material that has a work function that is substantially lower than the work function of the material included in the resistive portions. For example, each of first oxygen getter layer 407, second oxygen getter layer 409, and third oxygen getter layer 411 may include a material that is one of hafnium, zirconium, and yttrium. Moreover, each of the oxygen getter layers and resistive portions may have a thickness that is relatively thin, such as less than 5 nm. For example, the oxygen getter layers may each have a thickness of 2 nm.

While FIG. 4 illustrates two resistive portions and three oxygen getter layers, any number of portions and layers may be included in ReRAM cell 400. For example, a portion of ReRAM cell 400, such as portion 420, may be repeated several times. Thus, portion 420 may be repeated multiple times to create a laminate stack that may include numerous alternating resistive portions and oxygen getter layers. In one example, ReRAM cell 400 may include four resistive portions and five oxygen getter layers.

### Processing Examples

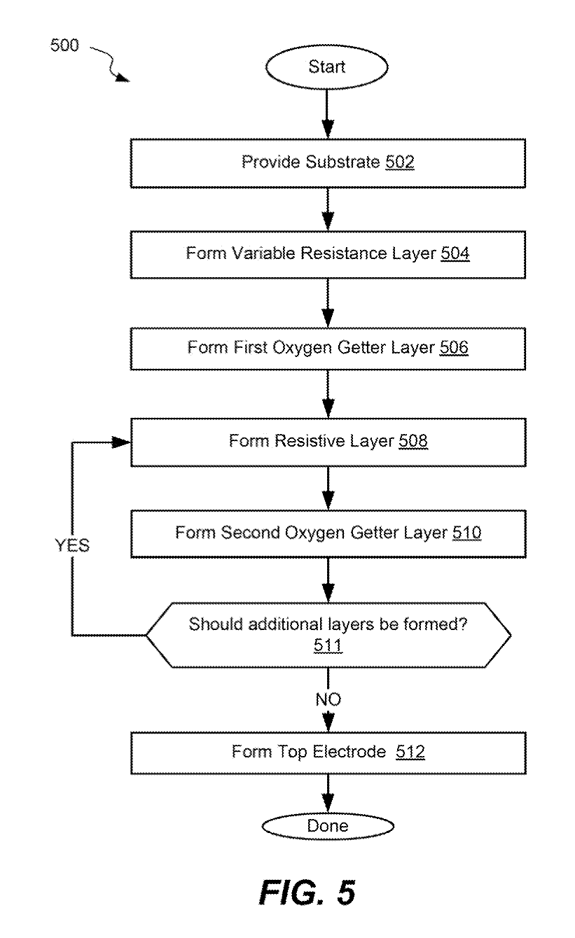

FIG. 5 illustrates a process flowchart corresponding to a method of fabricating a ReRAM cell, in accordance with some embodiments. Method 500 may commence with providing a substrate during operation 502. The substrate may include one or more components, such as a first signal line, a first electrode, and a current steering element. In other embodiments, method 500 involves forming the first signal line, the first electrode and/or, for example, the current steering element on the substrate, either of which may be operable as an electrode. The signal line can be made of silicon (e.g., doped polysilicon), a silicide, titanium nitride, or other appropriate materials listed elsewhere in this document. For example, a titanium nitride layer may be formed using PVD or other suitable deposition techniques. Deposition of the titanium nitride layer may be performed using a titanium target in a nitrogen atmosphere maintained at a pressure of between about 1-20 millitorr. The power may be maintained at 150-500 Watts/cm² with resulting in a deposition rate of about 0.05-0.5 nm per second. These process parameters are provided as examples and generally depend on deposited materials, tools, deposition rates, and other factors. Other processing techniques, such as ALD, PLD, CVD, evaporation, and the like can also be used to deposit the first signal line and, in some embodiments, the current steering element.

Method 500 may proceed with forming a variable resistance layer during operation 504. The variable resistance layer may be formed directly over the substrate or current steering element, if included. Thus, the variable resistance layer may directly interface the current steering element. In some embodiments, the embedded resistor may or may not be separated by one or more other layer, e.g., an interface layer that prevents diffusion of materials between the embedded resistor and the variable resistance layer. As similarly discussed above, the variable resistance layer may include a material, such as silicon oxide, and may have a thickness of about 1 nm. Any suitable deposition technique may be used to form the resistive switching layer, such as an atomic layer deposition (ALD) process or a physical vapor deposition (PVD) process. Other processing techniques, such as pulsed laser deposition (PLD), and chemical vapor deposition (CVD), evaporation, and the like may also be used to deposit the variable resistance layer.

Method 500 may proceed with forming a first oxygen getter layer during operation 506. The first oxygen getter layer may be formed directly over the variable resistance layer and may directly interface the variable resistance layer. The first oxygen getter layer may be made of a material such as hafnium, zirconium, and yttrium. The first oxygen getter layer may be formed using any suitable deposition technique such as ALD, PVD, PLD, or CVD. In some embodiments, relatively thick layers may be formed using a PVD process. Moreover, relatively thin layers, such as those included in nanolaminate stacks, may be formed using an ALD process.

Method 500 may proceed with forming a resistive layer during operation 508. Various examples of resistive layers are described above with reference to FIG. 3. In some embodiments, the resistive layer is formed from metal silicon nitride, such as tantalum silicon nitride, hafnium silicon nitride, and molybdenum silicon nitride. According to some embodiments, the resistive layer, or a portion thereof, is formed directly on the first oxygen getter layer and interfaces the first oxygen getter layer. Moreover, the resistive layer may be formed using any suitable deposition technique such as ALD, PVD, PLD, or CVD.

Method 500 may proceed with forming a second oxygen getter layer during operation 510. As similarly discussed above with reference to the first oxygen getter layer, the second oxygen getter layer may be formed directly over the resistive layer and may directly interface the resistive layer. The second oxygen getter layer may be made of a material such as hafnium, zirconium, and yttrium. The second oxygen getter layer may be formed using any suitable deposition technique such as ALD, PVD, PLD, or CVD.

In some embodiments, operations 506 through 510 may be part of a single deposition process. For example, method 500 may proceed by forming the resistive layer which may be a film of metal silicon nitride. While the resistive layer is being formed, an oxygen getter material may be pulsed, or periodically introduced. For example, during a PVD deposition process in which the resistive layer is being deposited, an oxygen getter material, such as zirconium, yttrium, or hafnium, may be pulsed by turning on and off a sputtering gun, or opening and closing a shutter associated with the oxygen getter material source. In this way, the oxygen getter material may be periodically introduced during the deposition of the resistive layer. Accordingly, the metal silicon nitride film may be sequentially doped with an oxygen getter material in different areas throughout the entire thickness of the resistive layer.

As similarly described above with reference to FIG. 4, the oxygen getter layers and resistive layer may be integrated as a nanolaminate stack. When integrated in this way, method 500 may repeat operations 508 and 510 any number of times until an entire stack is formed. For example, as previously discussed with reference to FIG. 4, a laminate stack may include alternating layers of an oxygen getter material and a metal silicon nitride. In some embodiments, the laminate stack may be formed using an atomic layer deposition process during operations 508-511. The atomic layer deposition process may include forming an oxygen getter layer by pulsing a source gas for the oxygen getter material. In some embodiments, the source gas may be a precursor for any of hafnium, zirconium, or yttrium. The pulsing of the source gas and subsequent reaction may result in the deposition of a layer of the oxygen getter material. In some embodiments, the atomic layer deposition process may also include forming a resistive layer or resistive portion by pulsing one or more source gases for a metal silicon nitride. The one or more source gases may include a silicon containing precursor and a metal containing precursor. The pulsing of the one or more source gases and subsequent reaction may result in the deposition of a layer of the metal silicon nitride. In this way, alternating layers of metal silicon nitride and oxygen getter material may be deposited. In some embodiments, forming the laminate stack may also include annealing the stack to interdiffuse the layers within the laminate stack. Accordingly, during operation 511, it may be determined whether an additional oxygen getter layer and resistive layer should be formed. If additional layers should be formed in the ReRAM cell, method 500 may return to operation 508. If it is determined that additional layers should not be formed, method 500 may proceed to operation 512.

During operation 512, method 500 may proceed with forming a third layer that is operable as a top electrode. As discussed above with reference to FIG. 3, the third layer may be made from a conductive material that has a desirable conductivity and work function, such as p-type polysilicon, n-type polysilicon, transition metals, transition metal alloys, transition metal nitrides, or transition metal carbides. For example, the third layer may include one or more of titanium (Ti), tungsten (W), tantalum (Ta), cobalt (Co), molybdenum (Mo), nickel (Ni), vanadium (V), hafnium (Hf) aluminum (Al), copper (Cu), platinum (Pt), palladium (Pd), iridium (Ir), or ruthenium (Ru). The third layer may have a thickness of between about 5 nm and about 500 nm. Any suitable deposition process may be used to form the third layer.

### Memory Array Examples

A brief description of memory arrays will now be described with reference to FIGS. 6A and 6B to provide better understanding to various aspects of thermally isolating structures provided adjacent to ReRAM cells and, in some examples, surrounding the ReRAM cells. ReRAM cells described above may be used in memory devices or larger integrated circuits (IC) that may take a form of arrays. FIG. 6A illustrates a memory array 600 including nine ReRAM cells 602, in accordance with some embodiments. In general, any number of ReRAM cells may be arranged into one array. Connections to each ReRAM cell 602 are provided by signal lines 604 and 606, which may be arranged orthogonally to each other. ReRAM cells 602 are positioned at crossings of signal lines 604 and 606 that typically define boundaries of each ReRAM cell in array 600.

Signal lines 604 and 606 are sometimes referred to as word lines and bit lines. These lines are used to read and write data into each ReRAM cell 602 of array 600 by individually connecting ReRAM cells to read and write controllers. Individual ReRAM cells 602 or groups of ReRAM cells 602 can be addressed by using appropriate sets of signal lines 604 and 606. Each ReRAM cell 602 typically includes multiple layers, such as first and second electrodes, variable resistance layer, embedded resistors, embedded current steering elements, and the like, some of which are further described elsewhere in this document. In some embodiments, a ReRAM cell includes multiple variable resistance layers provided in between a crossing pair of signal lines 604 and 606.

As stated above, various read and write controllers may be used to control operations of ReRAM cells 602. A suitable controller is connected to ReRAM cells 602 by signal lines 604 and 606 and may be a part of the same memory device and circuitry. In some embodiments, a read and write controller is a separate memory device capable of controlling multiple memory devices each one containing an array of ReRAM cells. Any suitable read and write controller and array layout scheme may be used to construct a memory device from multiple ReRAM cells. In some embodiments, other electrical components may be associated with the overall array 600 or each ReRAM cell 602. For example, to avoid the parasitic-path-problem, i.e., signal bypasses by ReRAM cells in their low resistive state (LRS), serial elements with a particular non-linearity must be added at each node or, more specifically, into each element. Depending on the switching scheme of the ReRAM cell, these elements can be diodes or varistor-type elements with a specific degree of non-linearity. In the same other embodiments, an array is organized as an active matrix, in which a transistor is positioned at each node or, more specifically, embedded into each cell to decouple the cell if it is not addressed. This approach significantly reduces crosstalk in the matrix of the memory device.

In some embodiments, a memory device may include multiple array layers as, for example, illustrated in FIG. 6B. In this example, five sets of signal lines 614a-b and 616a-c are shared by four ReRAM arrays 612a-c. As with the previous example, each ReRAM array is supported by two sets of signal lines, e.g., array 612a is supported by 614a and 616a. However, middle signal lines 614a-b and 616b, each is shared by two sets ReRAM arrays. For example, signal line set 614a provides connections to arrays 612a and 612b. First and second sets of signal lines 616a and 616c are only used for making electrical connections to one array. This 3-D arrangement of the memory device should be distinguished from various 3-D arrangements in each individual ReRAM cell.

### CONCLUSION

Although the foregoing examples have been described in some detail for purposes of clarity of understanding, the invention is not limited to the details provided. There are many alternative ways of implementing the invention. The disclosed examples are illustrative and not restrictive.

1. A resistive switching nonvolatile memory element comprising:
a first layer operable as a bottom electrode;
a second layer operable to switch between at least a first resistive state and a second resistive state in response to an applied voltage;
a third layer comprising a first oxygen getter material;
a fourth layer comprising a metal silicon nitride,
wherein the fourth layer has a substantially constant resistance at voltages less than or equal to the applied voltage;
a fifth layer comprising a second oxygen getter material,
wherein the first oxygen getter material and the second oxygen getter material are each more reactive with oxygen than the metal silicon nitride,
wherein a first work function of the first oxygen getter material and a second work function of the second oxygen getter material are each substantially lower than a third work function of the metal silicon nitride;
a sixth layer operable as a top electrode;
a seventh layer having a substantially constant resistance at voltages less than or equal to the applied voltage,
wherein the seventh layer directly interfaces the fifth layer; and
an eighth layer formed between the seventh layer and the sixth layer,
wherein the eighth layer includes a third oxygen getter material having a fourth work function that is substantially lower than the third work function of the metal silicon nitride.

2. The resistive switching nonvolatile memory element of claim 1, wherein the third layer and the fifth layer each comprise one of hafnium, zirconium, and yttrium.

3. The resistive switching nonvolatile memory element of claim 1, wherein the third layer and the fifth layer each have a thickness of between about 10 nm and 30 nm.

4. The resistive switching nonvolatile memory element of claim 1, wherein the fourth layer comprises tantalum silicon nitride.

5. The resistive switching nonvolatile memory element of claim 1, wherein the fourth layer has a thickness of between about 5 nm and 10 nm.

6. The resistive switching nonvolatile memory element of claim 1, wherein the fifth layer directly interfaces the fourth layer.

7. (canceled)

8. The resistive switching nonvolatile memory element of claim 1, wherein the seventh layer comprises a metal silicon nitride, and wherein the eighth layer comprises one of zirconium, yttrium and hafnium.

9. The resistive switching nonvolatile memory element of claim 1, wherein the fourth layer includes a dopant.

10. The resistive switching nonvolatile memory element of claim 9, wherein the dopant is one of hafnium, zirconium, and yttrium.

11. The resistive switching nonvolatile memory element of claim 1, wherein the second layer comprises one of hafnium oxide, titanium oxide, strontium titanium oxide, and hafnium silicon oxide.

12. The resistive switching nonvolatile memory element of claim 1, wherein the second layer comprises, at least in part, amorphous silicon oxide.

13. The resistive switching nonvolatile memory element of claim 1, wherein the first layer and the sixth layer comprise titanium nitride.

14. A method for forming a resistive switching nonvolatile memory element, the method comprising:
forming a first layer operable as a bottom electrode;
forming a second layer operable to switch between at least a first resistive state and a second resistive state in response to an applied voltage;
forming a third layer comprising a first oxygen getter material;
forming a fourth layer comprising a metal silicon nitride,
wherein the fourth layer has a substantially constant resistance at voltages less than or equal to the applied voltage;
forming a fifth layer comprising a second oxygen getter material,
wherein the first oxygen getter material and the second oxygen getter material are each more reactive with oxygen than the metal silicon nitride,
wherein a first work function of the first oxygen getter material and a second work function of the second oxygen getter material are each substantially lower than a third work function of the metal silicon nitride;
forming a sixth layer operable as a top electrode;
forming a seventh layer having a substantially constant resistance at voltages less than or equal to the applied voltage,
wherein the seventh layer directly interfaces the fifth layer; and
forming an eighth layer between the seventh layer and the sixth layer,
wherein the eighth layer includes a third oxygen getter material having a fourth work function that is substantially lower than the third work function of the metal silicon nitride.

15. The method of claim 14, wherein the third layer and the fifth layer each comprise one of hafnium, zirconium, and yttrium.

16. (canceled)

17. The method of claim 14, wherein the forming of the first layer, the second layer, the third layer, the fourth layer, the fifth layer, and the sixth layer comprise using an atomic layer deposition process.

18. The method of claim 17, wherein the forming of the fourth layer comprises:
forming a film of a metal silicon nitride; and
pulsing hafnium during the forming of the film.

19. The method of claim 17, wherein the forming of the fourth layer comprises:
forming a film of a metal silicon nitride; and
forming a laminate of hafnium over the film.

20. The method of claim 14, wherein the forming of the first layer, the second layer, the third layer, the fourth layer, the fifth layer, and the sixth layer comprise using a physical vapor deposition process.
